(19) United States
(12) Patent Application Publication
(10) Pub. No.: US 2025/0198946 A1
(43) Pub. Date: Jun. 19, 2025

(54) WAFER ALIGNMENT, CLEANLINESS, AND SURFACE QUALITY VERIFICATION USING LASER LIGHT SCATTERING

(71) Applicant: Axcelis Technologies, Inc., Beverly, MA (US)

(72) Inventors: Phillip Geissbuhler, Winchester, MA (US); FHM Faridur Rahman, Boxford, MA (US); Neil J. Bassom, Hamilton, MA (US)

(21) Appl. No.: 18/980,276

(22) Filed: Dec. 13, 2024

Related U.S. Application Data
(60) Provisional application No. 63/610,439, filed on Dec. 15, 2023.

(51) Int. Cl. G01N 21/95; H01L 21/67; H01L 21/677

(52) U.S. Cl. CPC G01N 21/9501; H01L 21/67213; H01L 21/67718

(57) ABSTRACT

A system and method are provided for determining one or more characteristics of a workpiece based on a scattered light beam distribution. An emission apparatus emits a coherent light beam on a surface of the workpiece and the coherent light beam may scatter upon interacting with the surface, defining the scattered light beam distribution. The scattered light beam distribution may be based on one or more attributes of the surface of the workpiece where one or more characteristics of the workpiece are determined based on the scattered light beam distribution. A receiver apparatus images the scattered light beam distribution, and a controller is configured to determine one or more characteristics of the workpiece based on the image data.

### REFERENCE TO RELATED APPLICATIONS

This application claims the benefit of U.S. Provisional Application Ser. No. 63/610,439 filed Dec. 15, 2023, entitled, “WAFER ALIGNMENT, CLEANLINESS, AND SURFACE QUALITY VERIFICATION USING LASER LIGHT SCATTERING”, the contents of all of which are herein incorporated by reference in their entirety.

### FIELD

The present invention relates generally to workpiece handling systems and processes, and more specifically to a system and method for selectively controlling and verifying one or more of an alignment, cleanliness, and surface quality of a workpiece in an ion implantation system.

### BACKGROUND

In semiconductor processing, many operations may be performed on a single workpiece or semiconductor wafer. In many processing operations, a particular orientation of the workpiece and/or knowledge of the position of the workpiece with respect to a workpiece holder is used to properly process or handle the workpiece. For example, operations such as an exchange of workpieces between transport carriers or storage cassettes and the processing system and a transfer of the workpieces from an atmospheric environment into an evacuated environment of a process chamber of the processing system through one or more load lock chambers may utilize specific orientation(s) or knowledge of the spatial position of the workpiece for proper workpiece handling and processing. Furthermore, an angle of presentation of a workpiece with respect to a process medium can affect the overall processing of the workpiece.

An orientation of the workpiece (e.g., notch alignment) may be performed within the evacuated environment or atmospheric environment via a light presence sensor, whereby a beam of light is emitted by a light emitter and directed toward the workpiece concurrent to a rotation of the workpiece with respect to the beam of light. A variation in light received by a light receiver can be then used to determine the position of a notch defined in the workpiece and/or an eccentricity of a position of the workpiece, depending on how the light is fully or partially received. One such system is disclosed in U.S. Pat. No. 5,740,034 to Hiroaki Saeki, whereby a waveform associated with the received light signals is utilized to determine the position of the notch and/or eccentric position of the workpiece.

### SUMMARY

The present disclosure provides a system, apparatus, and method for determining a position of a workpiece with respect to a workpiece support, as well as determining one or more characteristics of a surface of the workpiece. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one example aspect of the present disclosure, a workpiece characterization system is provided, wherein the workpiece characterization system comprises a workpiece support having a support surface configured to selectively support a semiconductor workpiece thereon. The semiconductor workpiece, for example, comprises a workpiece surface having one or more attributes. An emission apparatus is further provided and configured to emit a coherent light beam onto the workpiece surface and to scatter the coherent light beam from the workpiece surface to define a scattered light beam distribution based, at least in part, on one or more attributes. A receiver apparatus is configured to sense the scattered light beam distribution, whereby a controller is configured to determine one or more characteristics of the semiconductor workpiece based, at least in part, on the scattered light beam distribution.

When using a coherent light source, the resulting scattered light provides information on both the periodic order of structures on the workpiece surface and subsurface as well as aperiodic structure of the workpiece surface and subsurface. Periodic structures (e.g., devices) on the workpiece will result in the scattered light beam distribution generating a diffraction pattern which, in turn, provides information about the periodic structure (e.g., spacing between periodic devices in both x and y directions, device size in both x and y directions, and orientation with respect to the workpiece support). Aperiodic structure of the workpiece surface (e.g., surface roughness, surface cleanliness, or the level of amorphization of the crystal surface) will manifest in light speckle. Analysis of positions, spot shape, and intensity of the scattered light beam distribution provides information on an orientation, cleanliness, and surface quality of the workpiece.

For example, one or more characteristics of the semiconductor workpiece comprises one or more orientations of the semiconductor workpiece with respect to the workpiece support and a physical condition of the semiconductor workpiece. The one or more attributes, for example, comprise one or more of a plurality of features defined on the workpiece surface, a location of the plurality of features on the workpiece surface, a condition of the plurality of features, and a contaminant on the workpiece surface.

In accordance with various examples, the scattered light beam distribution comprises a diffraction pattern having one or more maxima arranged along a first axis based on the spacing of the plurality of features with respect to the emission apparatus, wherein each of the one or more maxima comprise a localized maximum scattered intensity. The controller, for example, may be further configured to determine the orientation of the semiconductor workpiece with respect to the workpiece support based on a disposition of the first axis relative to a reference axis. In one example, the reference axis is based on a predetermined position of the emission apparatus with respect to one or more support positions of the workpiece support.

A positioning apparatus may be further operably coupled to the workpiece support, wherein the positioning apparatus is configured to selectively position the workpiece support in one or more support positions with respect to the emission apparatus. The controller, for example, may be further configured to determine one or more characteristics of the semiconductor workpiece based on one or more support positions of the workpiece support.

In one example, the positioning apparatus is configured to selectively rotate the workpiece support with respect to a support axis, thereby selectively varying the diffraction pattern. Accordingly, the controller may be further configured to determine the orientation of the semiconductor workpiece with respect to the workpiece support based on the selective variation of the diffraction pattern. The support axis, for example, may be parallel to the support surface or perpendicular to the support surface.

One or more characteristics of the semiconductor workpiece, for example, may comprise one of a tilt angle of the workpiece surface relative to the support axis when the support axis is parallel to the support surface and a twist angle of the workpiece surface relative to the support axis when the support axis is perpendicular to the support surface.

In another example, an ion implantation system is configured to direct an ion beam toward the semiconductor workpiece, wherein one or more support positions of the workpiece support are associated with an implantation angle of the ion beam with respect to the semiconductor workpiece. The ion implantation system, for example, comprises a process chamber, wherein the positioning apparatus is configured to selectively position the workpiece support within the process chamber, and wherein one or more positions of the workpiece support are within the process chamber.

The process chamber, for example, may comprise one or more windows, wherein the emission apparatus and the receiver apparatus are external to the process chamber. As such, the coherent light beam and the scattered light beam distribution are configured to pass through one or more windows, respectively.

In one example, the emission apparatus comprises a laser having a predetermined wavelength selected from a range between approximately 400 nm and approximately 700 nm. In another example, the receiver apparatus comprises one or more of a laser sensor or an image sensor, wherein the image sensor can be configured to directly receive the scattered light beam distribution, or to view a projection of the scattered light beam distribution onto a screen or other surface.

According to another example aspect of the disclosure, a system is provided for determining an orientation of a semiconductor workpiece on a workpiece support. The system may comprise a laser emitting apparatus configured to emit a laser beam onto a surface of the semiconductor workpiece and to scatter the laser beam from the surface to define a scattered light beam distribution based, at least in part, on one or more attributes of the surface of the workpiece. An image sensor of the system may be configured to sense the scattered light beam distribution, wherein the scattered light beam distribution defines a diffraction pattern having a plurality of maxima arranged along a first axis. Further, the system may comprise a controller configured to determine an orientation of the semiconductor workpiece with respect to the workpiece support based, at least in part, on an orientation of the first axis with respect to a reference axis.

The orientation of the semiconductor workpiece with respect to the workpiece support, for example, may comprise a tilt angle of the surface of the semiconductor workpiece relative to a support plane of the workpiece support and a twist angle of the surface of the semiconductor workpiece relative to a reference axis defined perpendicular to the support plane of the workpiece support.

The controller may be configured to determine the highest intensity of the plurality of maxima, thereby defining a first maximum of the plurality of maxima. The controller may be further configured to determine either the tilt angle, or the twist angle, or both based on a predetermined correction factor and a distance between the first maximum and one or more of the first reference axis and a second reference axis, wherein the second reference axis is perpendicular to the first reference axis. In accordance with yet another example aspect of the disclosure, a method is provided for determining an orientation of a semiconductor workpiece on a workpiece support. The method comprises emitting a coherent light beam onto a surface of the workpiece and sensing the pattern of the scattered light beam having a plurality of maxima arranged along a first axis. The method further comprises determining the orientation of the semiconductor workpiece based on the light pattern and a position of the workpiece support. The orientation of the semiconductor workpiece, for example, may comprise a position of the workpiece with respect to a center axis of the workpiece support and is based on an angle between the first axis and a reference axis. The orientation, for example, may further comprise a tilt position of a surface of the workpiece relative to a reference plane, wherein the tilt position is based on the distance of a center point of the plurality of maxima relative to a second reference axis.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages, and novel features of the invention will become apparent from the following detailed description of the invention when considered in conjunction with the drawings.

### BRIEF DESCRIPTION OF THE DRAWINGS

FIG. 1 is a block diagram illustrating an ion implantation system for determining one or more characteristics of a workpiece based on scattered light beam distribution in accordance with some aspects of the present disclosure.

FIG. 2 is a schematic diagram illustrating a workpiece comprising a plurality of devices arranged thereon in accordance with some aspects of the present disclosure.

FIG. 3 is a schematic diagram illustrating an emission apparatus for generating a scattered light beam distribution such as a diffraction pattern to determine a twist alignment in accordance with some aspects of the present disclosure.

FIGS. 4-5 are schematic diagrams illustrating scattered light beam distributions in accordance with some aspects of the present disclosure.

FIGS. 6A-6B are schematic diagrams illustrating an emission apparatus for generating a scattered light beam distribution to determine a tilt alignment in accordance with some aspects of the present disclosure.

FIG. 7 is a schematic diagram illustrating a scattered light beam distribution in accordance with some aspects of the present disclosure.

FIG. 8 is a schematic diagram illustrating an emission apparatus for generating a scattered light beam distribution to determine a correction factor in accordance with some aspects of the present disclosure.

FIG. 9 is a schematic diagram illustrating translation of a scattered light beam distribution in accordance with some aspects of the present disclosure.

FIG. 10 is a process flow for determining one or more characteristics of a workpiece based on a scattered light beam distribution.

FIG. 11 is a block diagram illustrating an ion implantation system in accordance with some aspects of the present disclosure.

### DETAILED DESCRIPTION

The present disclosure thus provides various systems and methods for selectively controlling and verifying one or more of an alignment, cleanliness, and surface quality of a workpiece in an ion implantation system. The systems and methods, for example, are configured to utilize one or more of a diffraction pattern and a speckle pattern of a scattered light beam distribution resulting from scattering of coherent light emitted by a coherent light source off the workpiece. Analysis of the resulting scattered light beam distribution is used to determine one or more characteristics of the workpiece positioned on a workpiece support.

Thus, to the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages, and novel features of the invention will become apparent from the following detailed description of the invention when considered in conjunction with the drawings.

Accordingly, the present invention will now be described with reference to the drawings, wherein like reference numerals may be used to refer to like elements throughout. It should be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced with or without these specific details.

In semiconductor processing, a single piece of equipment (e.g., an ion implantation system) may be used to process potentially thousands of workpieces (e.g., semiconductor wafers) throughout its lifetime. One aspect of the functionality of such equipment is their ability to determine an alignment of the workpiece during operation. Given that many semiconductor devices have feature sizes in the range of nanometers, a high level of precision, and therefore alignment, is often required.

As a result, semiconductor processing equipment often includes equipment capable of aligning workpieces that can have the potential to fail or become de-calibrated over time, which can result in a workpiece that is mis-aligned during processing. For example, in an ion implantation system, a workpiece may be attached to a chuck that is coupled to a device such as a robotic arm. At a given time, the relative position of the chuck and the robotic arm can be determined via mechanical coupling. As such, the position of the workpiece with respect to the chuck can be inferred. However, since the position or alignment of the workpiece with respect to the chuck can vary during handling of the workpiece, simply knowing the position of the chuck may not accurately reflect the position or alignment of the workpiece with respect to the process medium. Such misalignment of workpieces can lead to increased production cost and waste. For example, if the workpiece is not placed in a predetermined alignment on the chuck, the determined position of the workpiece may be inaccurate, which can result in inaccurate ion implantation.

The present disclosure contemplates the novel use of a laser in order to minimize alignment errors between a workpiece and chuck. A semiconductor workpiece may comprise potentially trillions of transistors having feature sizes on the order of nanometers. During semiconductor manufacturing, many copies of a chip may be created on a single semiconductor workpiece, which results in features (e.g., devices) of the chip being repeated across the workpiece with high periodicity. The present invention appreciates that the high periodicity of the features, combined with the small feature size, provides an optimal scenario for generating what is known as a “diffraction pattern”.

A “diffraction pattern” refers to an effect that occurs when highly coherent light is scattered by a target surface with highly periodic structure (e.g., a surface of the semiconductor workpiece). The scattering of the highly coherent light causes constructive and destructive interference to occur, which forms both a diffraction pattern (due to the periodic structure) and a speckle pattern (due to the aperiodic surface structure) on a receiving surface. The resulting scattered light pattern may be based, at least in part, on one or more attributes of the surface of the semiconductor workpiece. As such, the scattered light pattern can be used to determine the one or more characteristics of the semiconductor workpiece.

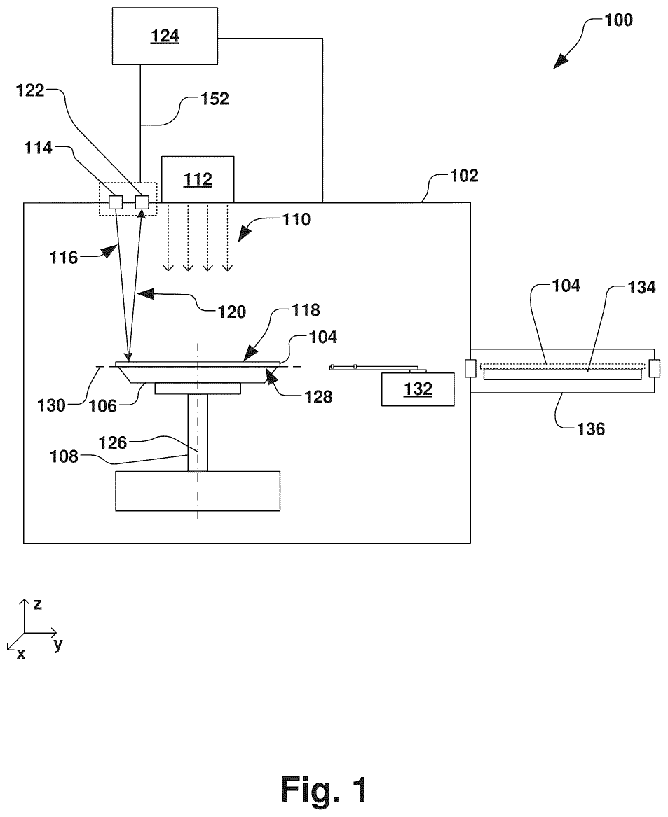

FIG. 1 illustrates an example of an ion implantation system 100 in accordance with some aspects of the present disclosure. The ion implantation system 100, for example, includes a process chamber 102. During ion implantation, a workpiece 104 is arranged within the process chamber 102. The workpiece may be, for example, a semiconductor wafer. The workpiece 104 is selectively supported by a workpiece support 106, which is operably coupled to a positioning apparatus 108. The positioning apparatus 108 is used to position the workpiece 104 within the process chamber 102 by moving the workpiece support 106. The workpiece support 106 may comprise a chuck (e.g., an electrostatic chuck (ESC)) or another suitable type of device. The positioning apparatus 108 may comprise a robotic arm, or the like, and may be controlled by software and/or hardware (e.g., control software and/or circuitry).

The ion implantation system 100 is configured to generate an ion beam 110 using an ion source 112. Using the ion beam 110, the ion implantation system 100 may perform ion implantation on the workpiece 104. During ion implantation, the orientation of the workpiece 104 with respect to the ion beam 110 may be manipulated using the positioning apparatus 108 and/or the workpiece support 106.

In order to verify an alignment of the workpiece 104 upon the workpiece support 106, the ion implantation system 100 further includes an emission apparatus 114 configured to emit a light beam 116 onto a surface 118 of the workpiece 104. In some examples, the emission apparatus 114 is a laser, in which case the light beam 116 is highly coherent. The light beam 116 scatters off the surface 118 to create a scattered light beam 120 which is sensed by a receiver apparatus 122. Although the scattered light beam 120 is illustrated as being sensed by the receiver apparatus 122 directly, in other examples, the scattered light beam distribution can be projected onto a surface (e.g., a screen—not shown), and the receiver apparatus is configured to sense the scattered light beam distribution that is projected onto the surface.

The scattered light beam 120 for example, comprises a diffraction pattern and/or a speckle pattern, as will be discussed in greater detail infra. The receiver apparatus 122 for example, comprises one or more of a laser sensor, an image sensor, or another suitable type of optical sensing device. In one example, the receiver apparatus 122 comprises an image sensor, wherein the image sensor directly receives the scattered light beam 120. In another example, the receiver apparatus 122 comprises an image sensor configured to view a projection of the scattered light beam 120 (e.g., a projection of the scattered light distribution onto a screen or other surface).

In some examples, the emission apparatus 114 emits laser light having a predetermined wavelength between approximately 400 nm and 700 nm. In some examples, the emission apparatus 114 and/or the receiver apparatus 122 are arranged within the process chamber 102. In other examples, the emission apparatus 114 and/or the receiver apparatus 122 are arranged outside of the process chamber 102, such that they emit/receive through one or more windows (not shown) of the process chamber 102. If the process chamber 102 is at low pressure (e.g., near vacuum) during processing, positioning the emission apparatus 114 and/or the receiver apparatus 122 outside of the process chamber can reduce a likelihood of overheating (e.g., due to inadequate airflow).

In some examples, a controller 124 is operably coupled to one or more elements within the process chamber 102. For example, one or more electrical connections may operably couple the controller 124 to one or more elements, and the controller 124 may control the one or more elements using electrical signals transmitted across the electrical connections. The one or more elements may comprise the workpiece support 106, the positioning apparatus 108, the ion source 112, etc. During ion implantation, the controller 124 may be configured to position the workpiece 104 within the process chamber 102 using the workpiece support 106 and/or the positioning apparatus 108 while simultaneously controlling the ion source 112 to emit an ion beam.

The controller 124 may further be configured to control (e.g., switch on/off) the emission apparatus 114 and/or the receiver apparatus 122 in order to determine the one or more characteristics of the workpiece 104. For example, the controller 124 may control the emission apparatus 114 to generate the scattered light beam distribution, and the controller 124 may receive/process data related to the scattered light beam distribution from the receiver apparatus 122. The controller 124 may determine the one or more characteristics of the workpiece 104 based on the data.

The one or more characteristics, for example, can comprise an orientation (e.g., an alignment) of the workpiece 104 with respect to the workpiece support 106. In one example, the alignment includes a twist angle of the workpiece 104 (e.g., the surface 118) relative to a first support axis 126. In some examples, the first support axis 126 is defined as being perpendicular to a support surface 128 of the workpiece support 106 when the workpiece 104 is loaded onto the workpiece support 106 (e.g., when the workpiece is in a “load position”). In another example, the alignment includes a tilt angle of the workpiece 104 (e.g., the surface 118) relative to a second support axis 130. In some examples, the second support axis 130 is defined as being parallel to the support surface 128 when the workpiece 104 is loaded onto the workpiece support 106 (e.g., when the workpiece is in the load position). The present disclosure further contemplates various configurations of the support surface 128 and the second support axis 130, such as being angularly offset (e.g., tilted) with respect to the ion beam 110, or perpendicular to the ion beam.

In some examples, the one or more characteristics of the workpiece 104 comprise a physical condition of the workpiece, such as one or more of a cleanliness, a surface quality, and a roughness of the workpiece. In another example, the one or more characteristics of the workpiece 104 comprise a presence of the workpiece on the workpiece support 106. In some further examples, the one or more characteristics of the workpiece 104 comprise one or more levels, degrees, or states of water absorption, surface amorphization, haze (e.g., phosphorous haze), and/or cleanliness associated with the workpiece. Characteristics of the surface quality of the workpiece 104 are examples of aperiodic surface structure(s) that can affect a so-called “speckle” or “speckle pattern” of the scattered light. Qualities of the speckle, for example, can manifest as changes to the shape, size, and intensity of diffraction spots of the diffraction pattern.

The one or more characteristics, for example, may be determined while the workpiece 104 resides on the workpiece support 106 prior to processing of the workpiece (e.g., before ion implantation), whereby the controller 124 is configured to verify the presence, alignment, cleanliness, etc. of the workpiece to ensure accurate or appropriate processing of the workpiece. For example, the workpiece 104 may be transferred to/from the workpiece support 106 by a transfer apparatus 132 before and/or after processing. The transfer apparatus 132 (e.g., a robotic device), for example, may be configured to selectively transfer the workpiece 104 between the process chamber 102 and an interim support 134. In the present example, the interim support 134 is positioned within a transfer chamber 136 (e.g., a loadlock chamber), whereby the transfer chamber is operably coupled to the process chamber 102 for enabling transport of the workpiece 104 to various other systems used to process the workpiece 104. It shall be appreciated, however, that the interim support 134 may be positioned within the process chamber 102 or another location, whereby the transfer apparatus 132 is configured to selectively transfer the workpiece 104 between the interim support and the workpiece support 106 for selective processing of the workpiece on the workpiece support.

The present disclosure appreciates that the transfer of the workpiece 104 between the workpiece support 106 and the interim support 134, for example, can subject the workpiece to displacement, such that upon being placed on the workpiece support, the alignment of the workpiece with respect to the workpiece support can vary based on the displacement. Absent countermeasures, such a variation in the alignment of the workpiece 104 with respect to the workpiece support 106, for example, may lead to deleterious effects on the workpiece after processing of the workpiece within the process chamber 102.

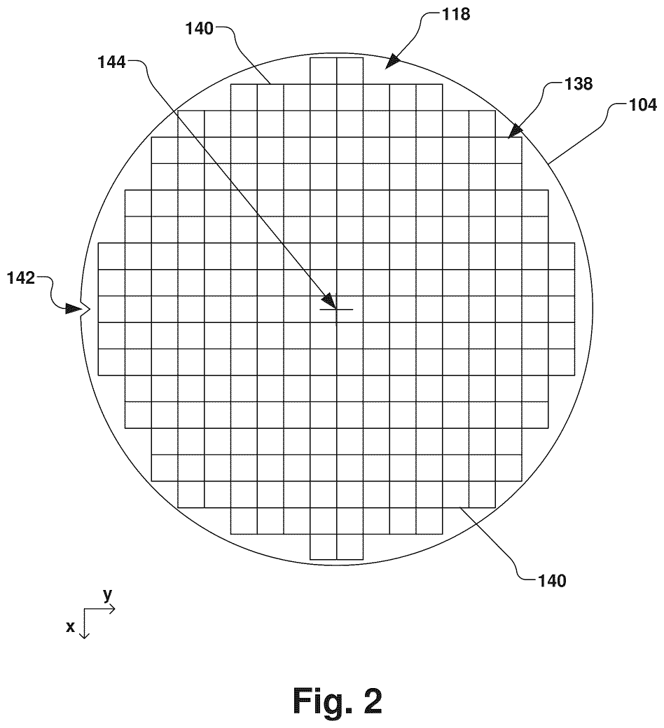

FIG. 2 illustrates an example of a top view of the workpiece 104 of FIG. 1 in accordance with various further aspects of the disclosure. The workpiece 104 illustrated in FIG. 2, for example, comprises one or more attributes 138. The one or more attributes 138, for example, may comprise a plurality of devices 140 arranged on or otherwise defining the surface 118 of the workpiece 104. The plurality of devices 140, for example, may comprise a plurality of features (not shown) that have been previously formed on the workpiece 104 using a variety of semiconductor processing steps such as doping (e.g., ion implantation), photolithography, metal depositions, oxide depositions, etching, polishing, etc.

Before each step of semiconductor processing, for example, the workpiece 104 may be aligned using an orientation feature 142 (e.g., a notch or flat) defined in the workpiece 104. The orientation feature 142, for example, may be used to align a twist angle of the workpiece 104 with respect to a process medium, such as an ion beam. As a result, the plurality of devices 140 may be formed on the workpiece 104 in a known alignment with respect to the orientation feature 142. Furthermore, a center 144 of the workpiece 104 may be aligned with a center (e.g., the first support axis 126 of the workpiece support 106 of FIG. 1), in order to ensure correct formation of the plurality of devices 140 during processing.

The plurality of devices 140 of FIG. 2, for example, may comprise a plurality of integrated circuits having many features (e.g., transistors) that are repeated at a small scale (e.g., on the order of nanometers). Typically, the plurality of devices 140, for example, are further spaced from one another in a relatively even manner across the surface 118 of the workpiece 104. As such, the disclosure presently appreciates that such an even spacing of the plurality of devices 140 and/or the repetitive nature of the features defining each device creates an optimal environment for generating a diffraction pattern, as previously described. The intensity and size of diffraction spots of the diffraction pattern may depend on several factors, such as the spacing between the plurality of devices 140, the size of the devices (or features defining the devices), the index of refraction of a material of the workpiece 104 (or coatings thereon), the wavelength of the light beam 116, the incident angle of the light beam onto the surface 118, and/or the penetration depth of the light beam into the surface 118 of the workpiece.

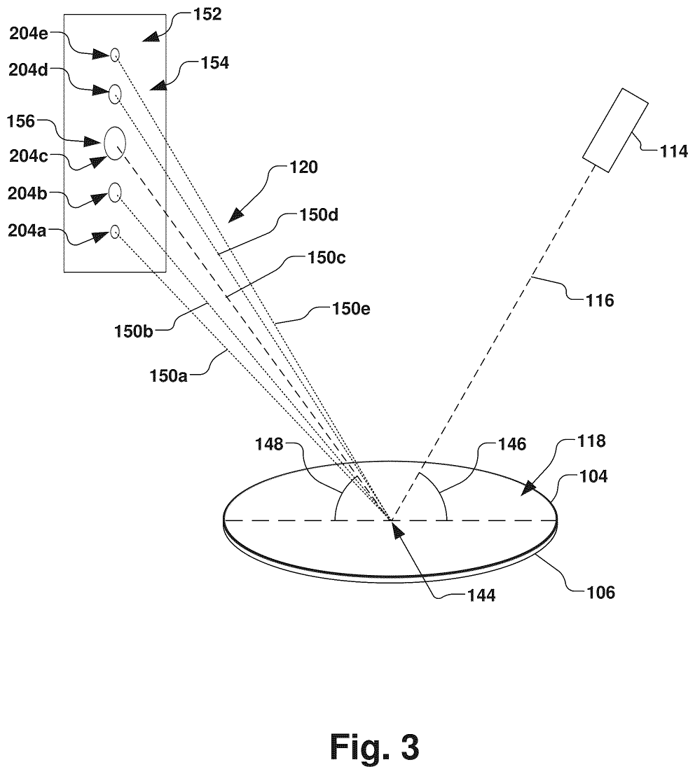

The present disclosure provides that, in order to verify the alignment of the workpiece 104 with respect to the workpiece support 106 of FIG. 1, the diffraction pattern may be generated by emitting coherent light as the light beam 116 onto the surface 118 using the emission apparatus 114, and sensing the diffraction pattern associated with the scattered light beam 120 by the receiver apparatus 122. The diffraction pattern, for example, may be further analyzed by the controller 124 in order to determine the alignment of the workpiece 104 with respect to the workpiece support 106. Generally referencing FIGS. 3-9, various examples associated with the determination of the one or more characteristics of the workpiece 104 based on the diffraction pattern will now be described.

FIG. 3 illustrates an example configuration of the emission apparatus 114 of FIG. 1. The emission apparatus 114 of FIG. 3, for example, is configured to emit the light beam 116 directed towards the surface 118 of the workpiece 104. In the present example, the light beam 116 is directed toward the center 144 of the workpiece 104. While not shown, the present disclosure contemplates other examples where the light beam 116 is directed toward other locations across the surface 118 of the workpiece. In general, the light beam 116, for example, is incident to the surface 118 of the workpiece 104 at an incident angle 146, and reflects off the surface at a specular reflection angle 148. The incident angle 146, for example, is equal to the specular reflection angle 148 when the surface 118 of the workpiece 104 is planar.

As a result of the repetitive nature of the one or more attributes 138 of the workpiece 104 described above (e.g., the plurality of devices 140 repetitively defined on the workpiece shown in FIG. 2), the light beam 116 further scatters off the surface 118 of the workpiece 104, thus defining a plurality of scattered light beams 150a-150e of the scattered light beam 120. The plurality of scattered light beams 150a-150e of the scattered light beam 120, for example, generally define a scattered light beam distribution 152. The scattered light beam distribution 152, for example, can take the form of a diffracted light beam distribution, also generally referred to as a diffraction pattern 154. Although only a limited number of the plurality of scattered light beams 150a-150e are illustrated for simplicity, additional light beams may also be formed as a result of the scattering. A specular reflection spot 156 (e.g., associated with scattered light beam 150c), for example, is at the center of the diffraction pattern 154 and is often the most intense spot of the scattered light beam distribution 152.

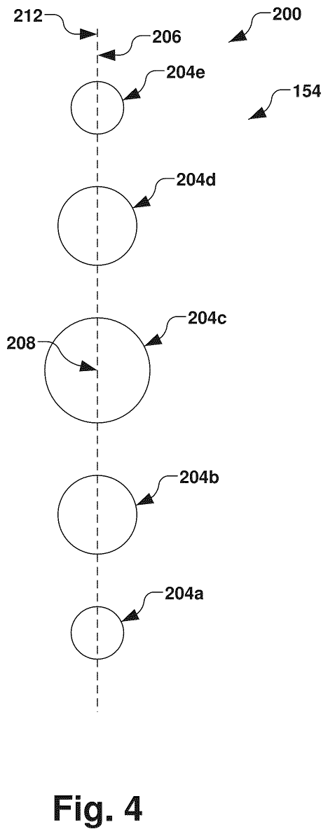

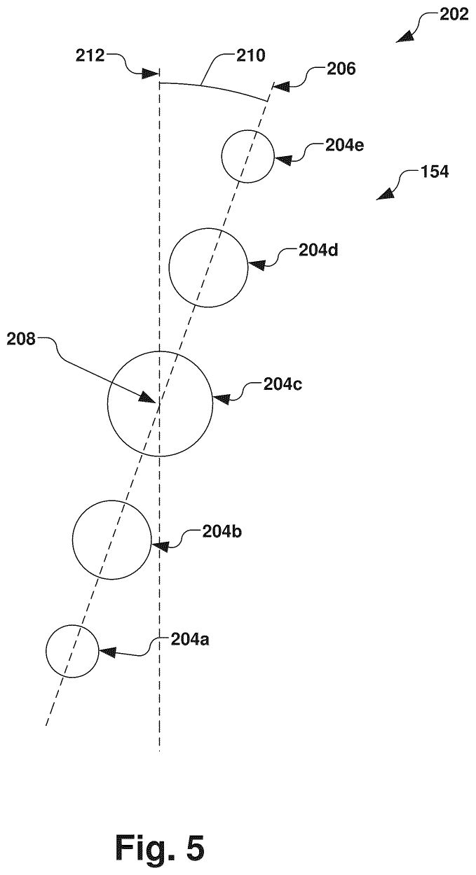

FIGS. 4-5 illustrate respective light beam distributions 200, 202 in accordance with further various example aspects of the present disclosure. The light beam distributions 200, 202, for example, may comprise respective diffraction patterns 154 corresponding to the scattered light beam 120 of FIG. 3 in various scenarios. The light beam distributions 200, 202 illustrated in FIGS. 4-5, for example, respectively comprise one or more spot maxima 204a-204e arranged along a first axis 206. The one or more spot maxima 204a-204e, for example, each comprise a localized maximum scattered intensity (e.g., at the center of each the one or more spot maxima, respectively). The light beam distributions 200, 202, for example, may be respectively based on a location of the plurality of features on the workpiece 104 with respect to the emission apparatus 114 of FIG. 3.

The one or more spot maxima 204a-204e, for example, comprise a maximum spot 204c arranged at a center 208 of the respective light beam distributions 200, 202. The maximum spot 204c, for example, exhibits a maximum size and/or intensity of the one or more spot maxima 204a-204e. As illustrated by the spot maxima 204a, 204b, 204d, and 204e, the spot maxima exhibit smaller size and/or intensity when located further from the maximum spot 204c at the center 208 of the respective light beam distributions 200, 202.

In one example, the present disclosure provides for a determination of a twist alignment of the workpiece 104 with respect to the workpiece support 106 of FIG. 1. As illustrated in the example shown in FIG. 5, such a determination of a twist alignment can be based on an offset angle 210 defined between the first axis 206 and a reference axis 212. The reference axis 212, for example, may be defined based on a relative position of a known object such as the workpiece support 106 of FIG. 1, or may be otherwise calibrated beforehand.

As illustrated in the example shown in FIG. 4, the first axis 206 is aligned with the reference axis 212 (e.g., at an offset angle of 0 degrees), indicating that the workpiece 104 of FIG. 1 is aligned with respect to the workpiece support 106. As illustrated in another example in FIG. 5, the first axis 206 is not aligned with respect to the reference axis 212, and is instead rotationally offset by the offset angle 210, thus indicating that the workpiece 104 of FIG. 1 is not aligned with respect to the workpiece support 106, whereby the offset angle indicates that the workpiece is rotated with respect to the workpiece support. As such, the controller 124 of FIG. 1 may determine a rotational alignment of the workpiece 104 with respect to the workpiece support 106 based on the offset angle 210 of FIG. 5. In one example, the controller 124 of FIG. 1 may be further configured to rotate the workpiece support 106 via a control of the positioning apparatus 108 until the first axis 206 is aligned with the reference axis 212 to yield the light beam distribution 200 as illustrated in FIG. 4. Once the first axis 206 is aligned with the reference axis 212, the workpiece 104 may be processed through the ion beam 110 or other process medium of FIG. 1.

In accordance with another aspect of the disclosure, the light beam distributions 200, 202 of FIGS. 4-5, for example, may be used to verify a presence of the workpiece 104 upon the workpiece support 106 of FIGS. 1 and 3. For example, when the one or more attributes 138 of FIG. 2 comprise periodic structures on the workpiece 104, the respective light beam distributions 200, 202 of FIGS. 4-5 may indicate that the light beam 116 is scattered in a predetermined manner, thus indicating that the workpiece 104 is present upon the workpiece support 106 of FIG. 1.

In alternative examples, the receiver apparatus 122 is configured to image the scattering of the light beam 116 from the workpiece support 106, whereby the controller 124 is configured to determine whether the workpiece 104 is present upon the workpiece support 106 based on a comparison between data received from the receiver apparatus 122 (e.g., a comparison of data associated with images of the light beam scattered from the workpiece support and a calibration workpiece known to be positioned on the workpiece support). Imaging data associated with various workpieces 104 and the workpiece support 106, for example, may be used to train the controller 124 to distinguish between various portions of the support surface 128 of the workpiece support and various surfaces of various workpieces.

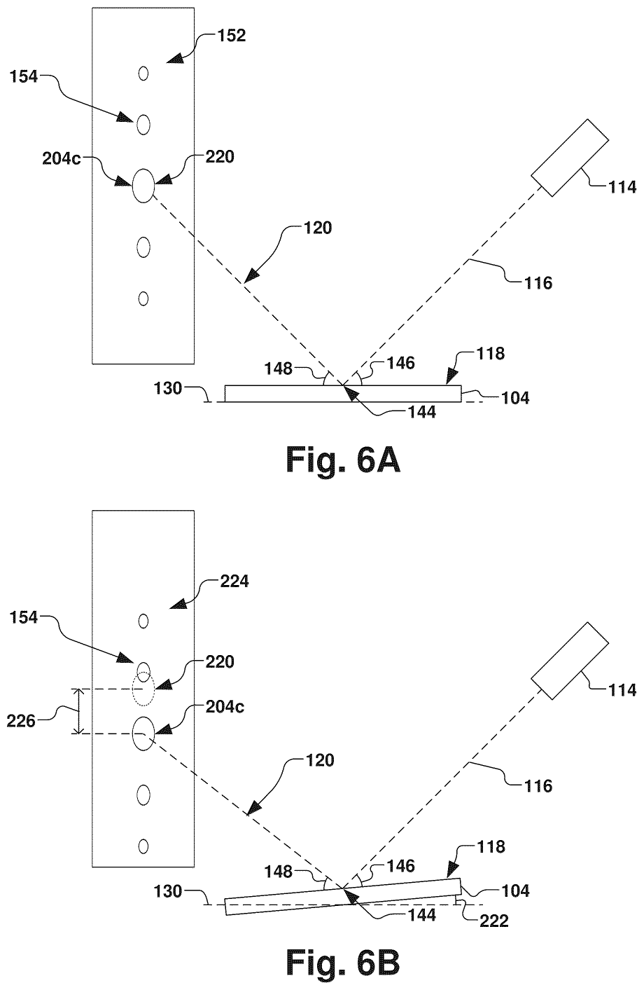

FIGS. 6A-6B illustrate various example configurations of the emission apparatus 114 of FIG. 1, whereby the emission apparatus is configured to emit the light beam 116 towards the surface 118 of the workpiece 104. In the illustrated example, the light beam 116 is incident to the center 144 of the workpiece 104. However, in alternative examples, the light beam 116 may be incident to a location of the workpiece 104 that is offset from the center 144 of the workpiece 104.

As illustrated in FIG. 6A, the surface 118 of the workpiece 104 is parallel with the second support axis 130, thus corresponding to a so-called tilt angle of 0 degrees. The light beam 116 is incident to the surface 118 of the workpiece 104 at the incident angle 146 to define the scattered light beam 120. Accordingly, the resulting scattered light beam distribution 152 in the present example illustrates the maximum spot 204c of the diffraction pattern 154 associated with the specular reflection angle 148 being centrally located at a first position 220. In some examples, the first position 220 corresponds to a reference position. It is again noted that when the surface 118 of the workpiece 104 is generally planar, for example, the incident angle 146 is equal to the specular reflection angle 148, as discussed above.

As illustrated in FIG. 6B, the workpiece 104 is tilted, such that the surface 118 of the workpiece 104 is non-parallel with the second support axis 130. Instead, the workpiece 104 is positioned at a tilt angle 222 with respect to the second support axis 130. As a result, the light beam 116, being incident to the surface 118 of the workpiece 104 at the incident angle 146, is scattered from the surface at the specular reflection angle 148, thus defining a scattered light beam distribution 224. The scattered light beam distribution 224, for example, differs from the scattered light beam distribution 152 of FIG. 6A in that the maximum spot 204c is offset by a distance 226 from the first position 220, as illustrated in FIG. 6B.

The scattered light beam distributions 152, 224, for example, may be sensed by the receiver apparatus 122 of FIG. 1, which sends corresponding data (e.g., imaging data) to the controller 124. The controller 124 may be thus configured to analyze the data to determine a tilt angle of the workpiece 104 with respect to the second support axis 130. Based on the distance 226 of FIG. 6B, for example, the controller 124 is configured to determine the tilt angle 222 of the workpiece 104. The determined tilt angle, for example, may be used to verify a tilt alignment before ion implantation.

It shall be noted that while only a limited number of the plurality of scattered light beams 150a-150e of FIG. 3 are illustrated in FIGS. 6A-6B for simplicity, any number of such scattered light beams may be present. Further, in alternative examples, some of the plurality of scattered light beams 150a-150e of FIG. 3 may not be present and/or are less intense, such that the scattered light beam distributions 152, 224 of FIGS. 6A-6B may be defined primarily by the maximum spot 204c. This may occur, for example, when the workpiece 104 is a blank semiconductor wafer having no devices yet formed thereon. The lack of features (e.g., devices) present on the workpiece 104, for example, may result in the diffraction pattern 154 being weaker or non-existent. In such scenarios, the maximum spot 204c may still be used to determine the characteristics of the workpiece 104.

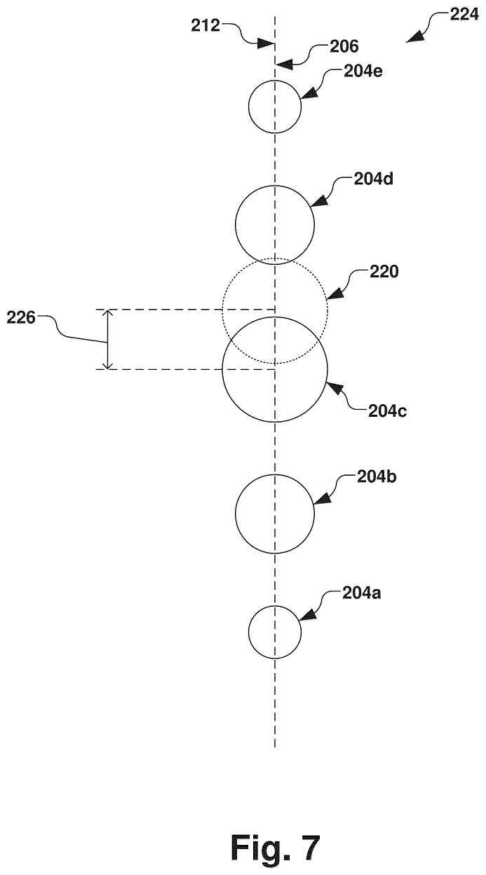

FIG. 7 illustrates another view of the scattered light beam distribution 224 of FIG. 6B. The scattered light beam distribution 224 of FIG. 7, for example, comprises one or more spot maxima 204a-204e arranged along the first axis 206, whereby the first axis is aligned with the reference axis 212. However, FIG. 7 differs from FIG. 4 in that the maximum spot 204c is offset by the distance 226 from the first position 220 (e.g., a reference position). The reference position may be determined based on a relative position of a known object, or calibrated beforehand. Although the first axis 206 in the example of FIG. 7 is illustrated as being aligned with the reference axis 212, in other examples, the first axis is not aligned (e.g., rotationally offset) with respect to the reference axis.

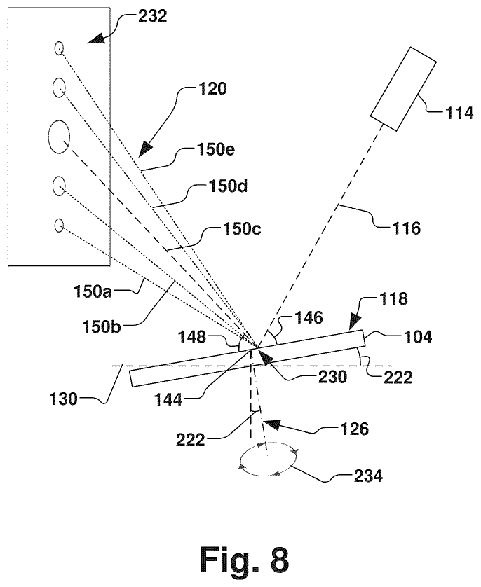

FIG. 8 illustrates another example configuration of the emission apparatus 114 of FIG. 1. The emission apparatus 114 of FIG. 8, for example, is configured to emit the light beam 116 towards the workpiece 104, whereby the light beam is incident to the surface 118 of the workpiece at an off-center location 230 that is offset from the center 144 of the workpiece. In one example, such an offset may be a result of the workpiece 104 being tilted at the tilt angle 222 with respect to the second support axis 130 of FIG. 1, as discussed above.

The light beam 116, for example, is incident to the surface 118 of the workpiece 104 at an incident angle 146 and reflects from the surface of the workpiece at the specular reflection angle 148, thereby defining scattered light beam distribution 232, as illustrated in FIG. 8. In some examples, the workpiece 104 is rotated about the first support axis 126 (e.g., via a control of the workpiece support 106 and/or the positioning apparatus 108 of FIG. 1) in order to detect the center 144 of the workpiece 104.

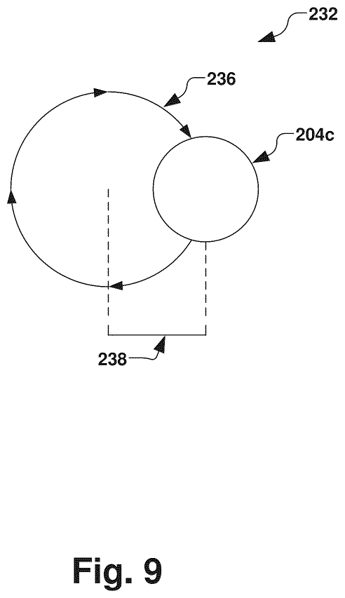

FIG. 9 illustrates another view of the scattered light beam distribution 232 of FIG. 8 in accordance with another example. Similar to the light beam distribution 200 of FIG. 4 discussed above, the scattered light beam distribution 232 of FIG. 9 comprises a maximum spot 204c. When the workpiece 104 is rotated about the first support axis 126, as illustrated by arrow 234 in FIG. 8, the maximum spot 204c may translate in, or otherwise define, a circular motion 236 shown in FIG. 9. The translation of the maximum spot 204c in the circular motion 236, for example, may be a result of the light beam 116 of FIG. 8 contacting the workpiece 104 at the off-center location 230. The translation of the maximum spot 204c, for example, may be sensed by the receiver apparatus 122 of FIG. 1, which is configured to transmit corresponding data (e.g., imaging data) to the controller 124. The controller 124, for example, may be configured to analyze the data to detect the center 144 of the workpiece 104 shown in FIG. 8. In some examples, analyzing the data may comprise determining a radius 238 of the circular motion 236, as illustrated in FIG. 9.

In some examples, the controller 124 of FIG. 1 is configured to selectively vary or adjust a position of the workpiece 104 (e.g., via a control of the workpiece support 106 and/or the positioning apparatus 108) based on the data collected by the receiver apparatus 122. The controller 124, for example, may be configured to control the position of the workpiece 104 and to align the workpiece by bringing the center 144 of the workpiece 104 into a desired alignment with the light beam 116. The controller 124, for example, may be configured to determine an alignment of the center 144 of the workpiece 104 with the light beam 116 (e.g., via the receiver apparatus 122) by observing an absence of the translation of the maximum spot 204c in the circular motion 236 of FIG. 9.

In other examples, the controller 124 is further configured to determine a correction factor based on the above-described data from the receiver apparatus 122. Based on the correction factor, for example, the calculation of the tilt angle (e.g., as in FIGS. 6-7) may be adjusted or otherwise controlled. Accordingly, an accuracy of the determination of the tilt angle is not negatively impacted by the light beam 116 being incident to the workpiece 104 at an off-center location (e.g., the off-center location 230 of FIG. 8).

Again, the controller 124 of FIG. 1 is configured to determine the one or more characteristics of the workpiece 104, such as water absorption, surface amorphization, phosphorous haze, and cleanliness, based on the scattered light beam 120 and/or the diffraction pattern 154, as discussed above. For example, such characteristics are associated with a surface quality of the workpiece 104, whereby an aperiodic surface structure can affect the speckle pattern of the scattered light beam distributions 152, whereby qualities of the speckle will manifest as changes to the shape, size, and intensity of the spot maxima 204a-204e, such as discussed in reference to FIG. 3.

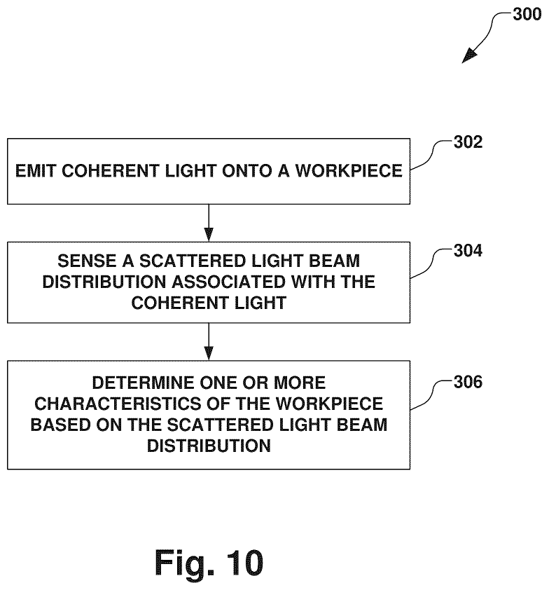

In accordance with the present disclosure, the system described herein enables a method 300 for determining one or more characteristics of a workpiece based on a scattered light beam distribution, as illustrated in flowchart form in FIG. 10. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 of FIG. 10 begins at act 302 with emitting coherent light onto a workpiece. Coherent light may be generated, for example, using a laser as previously described. The coherent light may scatter off the workpiece to generate a scattered light beam distribution.

Act 304, for example, comprises sensing the scattered light beam distribution. The sensing may be performed, for example, using a sensing apparatus as previously described.

Act 306, for example, comprises determining one or more characteristics based on the scattered light beam distribution. One or more characteristics may be determined, for example, by a controller using the techniques described with reference to FIGS. 1-9 and throughout the present disclosure.

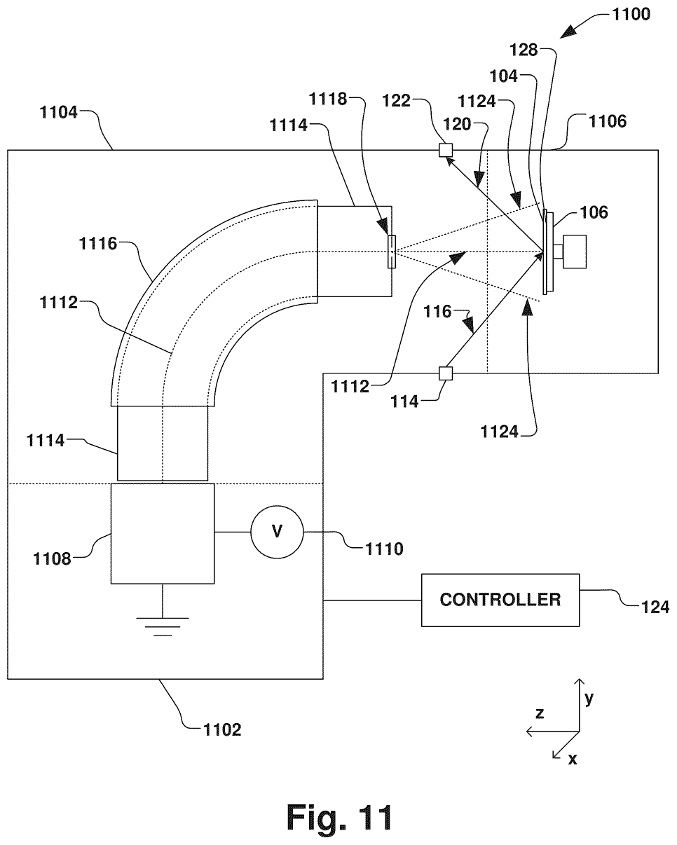

FIG. 11 illustrates an example of ion implantation system 1100 in accordance with some aspects of the present disclosure. The ion implantation system 1100 is illustrated having a terminal 1102, a beamline assembly 1104, and an end station 1106. The terminal 1102, for example, comprises an ion source 1108 powered by a high voltage power supply 1110. The ion source produces and directs an ion beam 1112 through the beamline assembly 1104, and ultimately, to the end station 1106. The ion beam 1112, for example, can take the form of a spot beam, pencil beam, ribbon beam, or any other shaped beam. The beamline assembly 1104 further has a beam guide 1114 and a mass analyzer 1116. A dipole magnetic field is established to pass only ions of appropriate charge-to-mass ratio through an aperture 1118 at an exit end of the beam guide 1114 to the workpiece 104 (e.g., a semiconductor wafer, display panel, etc.) positioned in the end station 1106. The workpiece 104 may be supported on the support surface 128 of the workpiece support 106. Further, the controller 124 is configured to control one or more components of the ion implantation system 1100.

The ion implantation system 1100 may include the emission apparatus 114 and the receiver apparatus 122 as described throughout the present disclosure. The emission apparatus 114 may be configured to emit the light beam 116 (e.g., a coherent light beam) on the workpiece 104 to generate a scattered light beam distribution. The receiver apparatus 122 may be configured to sense the scattered light beam distribution, and send corresponding data to the controller 124. The controller 124 may be configured to determine one or more characteristics of the workpiece 104 based on the scattered light beam distribution, as described throughout the present disclosure.

Although the invention has been illustrated and described with respect to one or more implementations, it will be understood that alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including any reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A workpiece characterization system comprising:
a workpiece support having a support surface configured to selectively support a semiconductor workpiece thereon, wherein the semiconductor workpiece comprises a workpiece surface having one or more attributes;
an emission apparatus configured to emit a coherent light beam onto the workpiece surface and to scatter the coherent light beam from the workpiece surface to define a scattered light beam distribution based, at least in part, on the one or more attributes;
a receiver apparatus configured to sense the scattered light beam distribution; and
a controller configured to determine one or more characteristics of the semiconductor workpiece based, at least in part, on the scattered light beam distribution.

2. The workpiece characterization system of claim 1, wherein the one or more characteristics of the semiconductor workpiece comprise one or more of an orientation of the semiconductor workpiece with respect to the workpiece support and a physical condition of the semiconductor workpiece.

3. The workpiece characterization system of claim 2, wherein the one or more characteristics of the semiconductor workpiece comprise one or more of a plurality of features defined on the workpiece surface, a location of the plurality of features on the workpiece surface, a condition of the plurality of features, and a contaminant on the workpiece surface.

4. The workpiece characterization system of claim 3, wherein the scattered light beam distribution comprises a diffraction pattern having one or more maxima arranged along a first axis based on the location of the plurality of features with respect to the emission apparatus, wherein each of the one or more maxima comprise a localized maximum scattered intensity.

5. The workpiece characterization system of claim 4, wherein the controller is further configured to determine the orientation of the semiconductor workpiece with respect to the workpiece support based on a disposition of the first axis relative to a reference axis.

6. The workpiece characterization system of claim 5, further comprising a positioning apparatus operably coupled to the workpiece support, wherein the positioning apparatus is configured to selectively position the workpiece support in one or more support positions with respect to the emission apparatus, wherein the controller is configured to determine the one or more characteristics of the semiconductor workpiece further based on the one or more support positions of the workpiece support.

7. The workpiece characterization system of claim 6, wherein the positioning apparatus is configured to selectively rotate the workpiece support with respect to a support axis, thereby selectively varying the diffraction pattern, and wherein the controller is further configured to determine the orientation of the semiconductor workpiece with respect to the workpiece support based on the selective variation of the diffraction pattern.

8. The workpiece characterization system of claim 7, wherein the support axis is parallel to the support surface or perpendicular to the support surface.

9. The workpiece characterization system of claim 8, wherein the one or more characteristics of the semiconductor workpiece comprises one of a tilt angle of the workpiece surface relative to the support axis when the support axis is parallel to the support surface and a twist angle of the workpiece surface relative to the support axis when the support axis is perpendicular to the support surface.

10. The workpiece characterization system of claim 6, wherein the reference axis is based on a predetermined position of the emission apparatus with respect to the one or more support positions of the workpiece support.

11. The workpiece characterization system of claim 6, further comprising an ion implantation system configured to direct an ion beam toward the semiconductor workpiece, wherein the one or more support positions of the workpiece support are associated with an implantation angle of the ion beam with respect to the semiconductor workpiece.

12. The workpiece characterization system of claim 11, wherein the ion implantation system comprises a process chamber, wherein the positioning apparatus is configured to selectively position the workpiece support within the process chamber, and wherein the one or more positions of the workpiece support are within the process chamber.

13. The workpiece characterization system of claim 12, wherein the process chamber comprises one or more windows, and wherein the emission apparatus and the receiver apparatus are external to the process chamber, wherein the coherent light beam and the scattered light beam distribution are configured to pass through the one or more windows, respectively.

14. The workpiece characterization system of claim 1, wherein the emission apparatus comprises a laser having a predetermined wavelength selected from a range between approximately 400 nm and approximately 700 nm.

15. The workpiece characterization system of claim 1, wherein the receiver apparatus comprises one or more of a laser sensor or an image sensor.

16. A system for determining an orientation of a semiconductor workpiece on a workpiece support, comprising:
a laser emitting apparatus configured to emit a laser beam onto a surface of the semiconductor workpiece and to scatter the laser beam from the surface to define a scattered light beam distribution based, at least in part, on one or more attributes of the surface of the semiconductor workpiece;
an image sensor configured to sense scattered light beam distribution, wherein the scattered light beam distribution defines a diffraction pattern having a plurality of maxima arranged along a first axis; and
a controller configured to determine the orientation of the semiconductor workpiece with respect to the workpiece support based, at least in part, on an orientation of the first axis with respect to a first reference axis.

17. The system of claim 16, wherein the orientation of the semiconductor workpiece with respect to the workpiece support comprises one or more of a tilt angle of the surface of the semiconductor workpiece relative to a support plane of the workpiece support and a twist angle of the surface of the semiconductor workpiece relative to reference axis defined perpendicular to the support plane of the workpiece support.

18. The system of claim 17, wherein the controller is further configured to determine a highest intensity of the plurality of maxima, thereby defining a first maximum of the plurality of maxima, and wherein the controller is configured to determine one or more of the tilt angle and the twist angle based on a predetermined correction factor and a distance between the first maximum and one or more of the first reference axis and a second reference axis, wherein the second reference axis is perpendicular to the first reference axis.

19. A method for determining an orientation of a semiconductor workpiece on a workpiece support, comprising:
emitting a coherent light beam onto a surface of the semiconductor workpiece;
sensing a scattering of the coherent light beam, wherein the scattering of the coherent light beam defines a light pattern having a plurality of maxima arranged along a first axis; and
determining the orientation of the semiconductor workpiece based on the light pattern and a position of the workpiece support, wherein the orientation of the semiconductor workpiece comprises a position of the semiconductor workpiece with respect to a center axis of the workpiece support and is based on an angle between the first axis and a reference axis.

20. The method of claim 19, wherein the orientation further comprises a tilt position of the surface of the semiconductor workpiece relative to a reference plane, wherein the tilt position is based on a distance of a center point of the plurality of maxima relative to a second reference axis.
